(19) United States
(12) Patent Application Publication
(10) Pub. No.: US 2008/0060793 A1
(43) Pub. Date: Mar. 13, 2008

(54) COOLER DEVICE

(76) Inventor: Tsung-Hsien Huang, I-Lan Hsien (TW)

Correspondence Address: PAI PATENT & TRADEMARK LAW FIRM, 1001 FOURTH AVENUE, SUITE 3200, SEATTLE, WA, 98154, US

(21) Appl. No.: 11/530,149

(22) Filed: Sep. 8, 2006

(51) Int. Cl. H05K 7/20; F28D 15/02

(52) U.S. Cl. 165/104.33; 361/700; 257/715; 29/890.032

(57) ABSTRACT

A cooler device includes a metal base member and a plurality of metal radiation fins. The metal base member has parallel locating grooves; the metal radiation fins are fastened to one another in a stack by respective hooked portions thereof or by means of closed-end heat tubes, the metal radiation fins each having backwardly curved and crimped bottom mounting portions respectively fitted into the locating grooves of the metal base and fixedly secured thereto by means of compacting the locating grooves of the metal base member without electroplating or using solder paste or bonding means.

### BACKGROUND OF THE INVENTION

(a) Field of the Invention

The present invention relates to a cooler device and more particularly to the mounting arrangement of the metal base member and metal radiation fins of a cooler device, which greatly increases the contact surface area between the metal base member and the metal radiation fins and is environmentally friendly.

(b) Description of the Prior Art

Conventional heat sinks are commonly comprised of a base member and a plurality of radiation fins arranged in parallel on the metal base member. The base member and the radiation fins are generally extruded from aluminum or copper. Therefore, the base member of a conventional heat sink is called the aluminum base or copper base. Further, regular heat sinks include heat sinks with heat tubes and heat sinks without heat tube. In a heat sink without heat tube, the radiation fins are arranged in parallel and fastened to one another by respective hooked portions thereof. In a heat sink with heat tubes, heat tubes are fastened to the radiation fins to secure the radiation fins together. Further, a heat sink may be provided with an electric fan to enhance heat dissipation.

Further, the radiation fins of a conventional heat sink are soldered to the base member with the application of a solder paste or bonding agent. Further, when fastening copper heat tubes to an aluminum base member, a nickel-plating procedure is necessary. The use of a solder paste or bonding agent or the application of a nickel-plating procedure greatly increases the manufacturing cost of the heat sink. Further, the application of a nickel-plating procedure is not environmentally friendly.

There are heat sinks in which the base member is secondarily processed to provide parallel mounting grooves and then the base member is compacted to secure the radiation fins in place after insertion of the radiation fins into the mounting grooves. However, the secondary processing of the base member greatly increases the cost. Further, the limited contact surface area between the base member and the radiation fins does not allow quick transmission of heat energy from the base member to the radiation fins for quick dissipation.

### SUMMARY OF THE INVENTION

The present invention has been accomplished under the circumstances in view. According to one aspect of the present invention, the cooler device comprises a metal base member, and a plurality of metal radiation fins mounted on the metal base member. The metal radiation fins each have at least one backwardly curved and crimped bottom mounting portion. The metal base member has a plurality of deep locating grooves, which receive the backwardly curved and crimped bottom mounting portions of the radiation fins; the metal base member is compressed to fixedly secure the backwardly curved and crimped bottom mounting portions of the radiation fins to the metal base member. Therefore, the radiation fins are quickly and easily affixed to the base member without electroplating or the use of solder paste or bonding means, i.e., the mounting procedure of the present invention is environmentally friendly.

According to another aspect of the present invention, each radiation fin has a plurality of backwardly curved and crimped bottom mounting portions respectively fastened to the base member. Therefore, the thickness of the bottom side of each radiation fin is relatively increased, i.e., the contact surface area between the radiation fins and the base member is relatively increased for quick transmission of heat energy from the base member to the radiation fins.

According to still another aspect of the present invention, the backwardly curved and crimped bottom mounting portions of said metal radiation fins can be made to show a U-shaped profile, a L-shaped profile, a triangular profile, an inverted T-shaped profile, or a scroll-shaped profile.

According to still another aspect of the present invention, each radiation fin has the bottom side turned backwards and crimped, therefore the bottom mounting side of each radiation fin has a certain wall thickness, and the base member can be directly extruded from aluminum or copper to provide the matching locating grooves for the mounting of the backwardly curved and crimped mounting portions of the radiation fins quickly and efficiently without a secondary processing.

### BRIEF DESCRIPTION OF THE DRAWINGS

FIG. 1 is an oblique elevation view of a cooler device in accordance with a first embodiment of the present invention.

FIG. 2 is an oblique elevation view of a base member for cooler device before formation of shadow transverse grooves according to the first embodiment of the present invention.

FIG. 3 is an exploded view of the cooler device according to the first embodiment of the present invention.

FIG. 4 is a sectional view of the cooler device according to the first embodiment of the present invention.

FIG. 5 is an exploded view in an enlarged scale of a part of the cooler device according to the first embodiment of the present invention.

FIG. 6 is an oblique elevation view of a cooler device according to a second embodiment of the present invention.

FIG. 7 is an exploded view of the cooler device according to the second embodiment of the present invention.

FIG. 8 is an elevational view showing a second form of the backwardly curved and crimped bottom mounting portion of the radiation fin.

FIG. 9 shows the backwardly curved and crimped bottom mounting portions of the second form of the radiation fins fastened to the base member according to the present invention.

FIG. 10 is an elevational view showing a third form of the backwardly curved and crimped bottom mounting portion of the radiation fin.

FIG. 11 shows the backwardly curved and crimped bottom mounting portions of the third form of the radiation fins fastened to the base member according to the present invention.

FIG. 12 is an elevational view showing a fourth form of the backwardly curved and crimped bottom mounting portion of the radiation fin.

FIG. 13 shows the backwardly curved and crimped bottom mounting portions of the fourth form of the radiation fins fastened to the base member according to the present invention.

FIG. 14 is an elevational view showing a fifth form of the backwardly curved and crimped bottom mounting portion of the radiation fin.

FIG. 15 shows the backwardly curved and crimped bottom mounting portions of the fifth form of the radiation fins fastened to the base member according to the present invention.

FIG. 16 is an oblique elevation view of a cooler device according to a third embodiment of the present invention.

FIG. 17 is an oblique elevation view of a cooler device according to a fourth embodiment of the present invention.

FIG. 18 is a top view of the cooler device according to the fourth embodiment of the present invention.

### DETAILED DESCRIPTION OF THE PREFERRED EMBODIMENTS

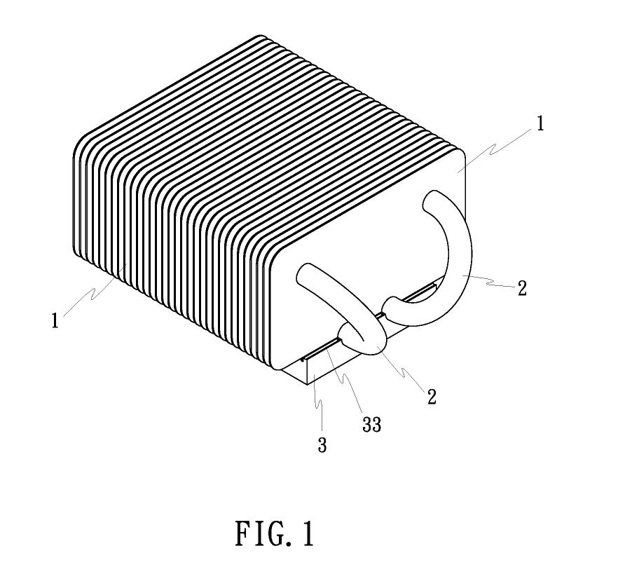

Referring to FIGS. 1˜5, a cooler device in accordance with a first embodiment of the present invention is shown comprised of a set of radiation fins 1, a plurality of heat tubes 2, and a base member 3.

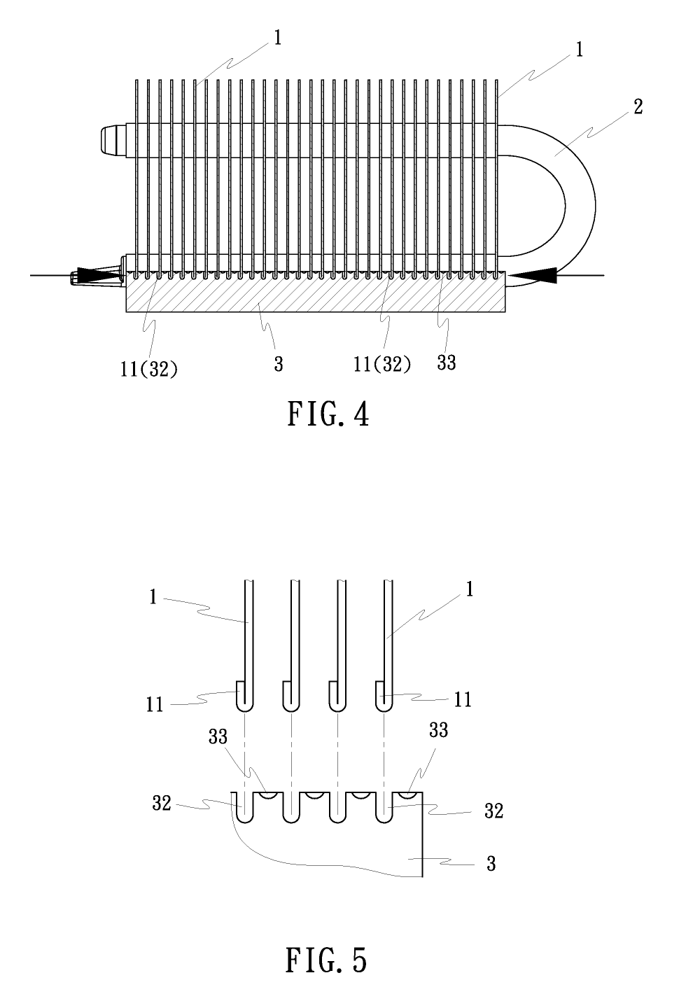

The radiation fins 1 have same or different shapes, and are arranged in parallel. Further, each radiation fin 1 has a plurality of backwardly curved and crimped bottom mounting portion 11 (see FIGS. 4 and 5).

The heat tubes 2 are double closed-end U-tubes filed with a working fluid (not shown) and fixedly fastened to the radiation fins 1 to keep the radiation fins 1 in parallel.

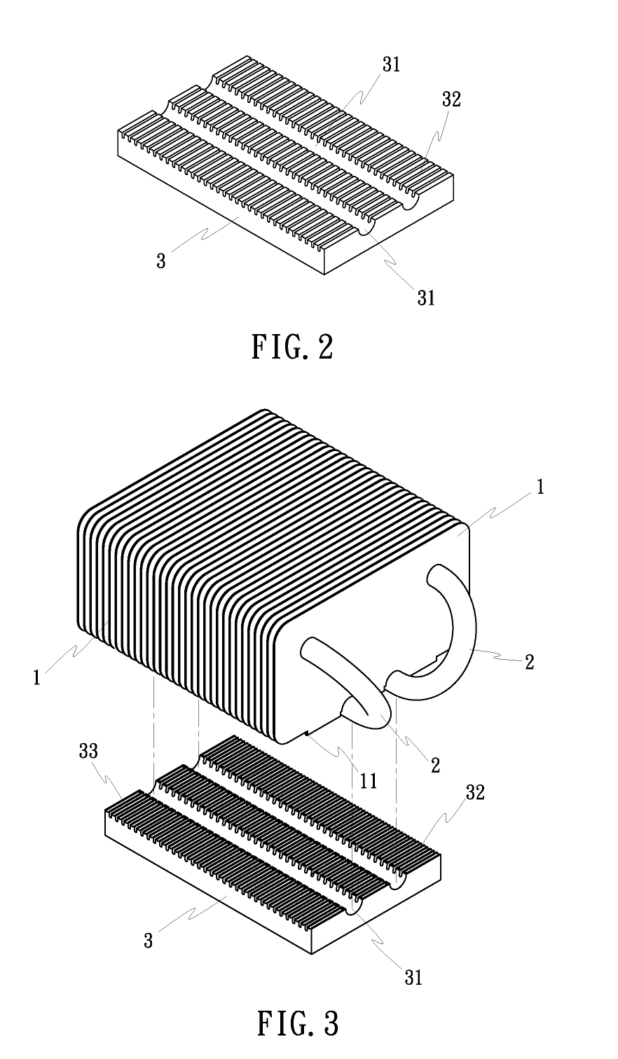

The base member 3 is a solid flat metal block extruded from aluminum or copper, having two longitudinal positioning grooves 31 (of semicircular cross section) formed on the top wall and respectively fitting under the periphery of a part of each of the heat tubes 2, a plurality of deep transverse locating grooves 32 formed on the top wall and adapted to receive the backwardly curved and crimped bottom mounting portions 11 of the radiation fins 1, and a plurality of shadow transverse grooves 33 formed on the top wall between each two adjacent deep transverse locating grooves 32. FIG. 2 is an oblique top elevation view of the base member 3 before the shadow transverse grooves 33 are formed.

After the backwardly curved and crimped bottom mounting portions 11 of the radiation fins 1 are inserted into the deep transverse locating grooves 32, the base member 3 is compressed (in the direction indicated by the arrowhead signs shown in FIG. 4) to secure the radiation fins 1 firmly in place. This radiation fin and base member mounting arrangement is easy and inexpensive. Because the invention eliminates the use of electroplating, solder paste, or other bonding means, the manufacturing cost of the cooler device is low and, the fabrication of the cooler device is environmentally friendly. Further, because extruding the base member 3 from aluminum or copper forms the deep transverse locating grooves 32, the invention eliminates a secondary processing process to form the transverse locating grooves on the base member.

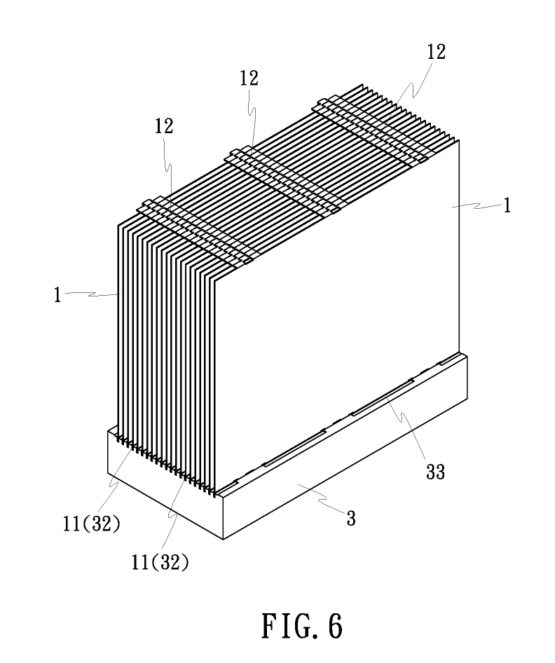

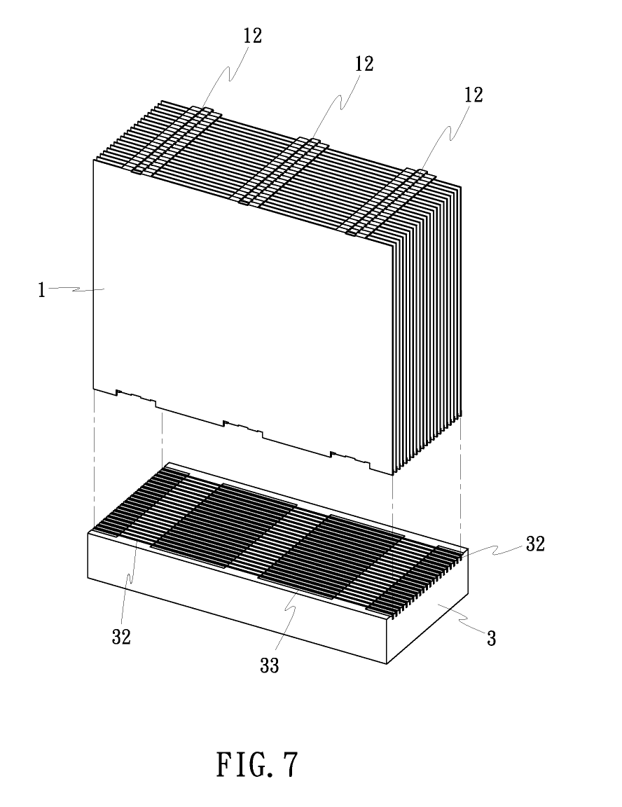

FIGS. 6 and 7 show a cooler device in accordance with a second embodiment of the present invention. According to this design, the cooler device is comprised of a set of radiation fins 1, and a base member 3.

The radiation fins 1 each have a plurality of hooked portions 12 protruded from one side, namely, the top side, and a plurality of backwardly curved and crimped bottom mounting portions 11. Further, the radiation fins 1 are flat metal sheet members of same or different contours. By means of hooking the hooked portions 12 of one radiation fin 1 to another, the radiation fins 1 are fastened together in a parallel manner.

The base member 3 is a solid flat metal block extruded from aluminum or copper, having a plurality of deep transverse locating grooves 32 formed on the top wall and adapted to receive the backwardly curved and crimped bottom mounting portions 11 of the radiation fins 1, and a plurality of shadow transverse grooves 33 formed on the top wall between each two adjacent transverse deep locating grooves 32.

After the backwardly curved and crimped bottom mounting portions 11 of the radiation fins 1 are inserted into the deep transverse locating grooves 32, the base member 3 is compressed to deform the shadow transverse grooves 33, thereby securing the radiation fins 1 firmly to the base member 3.

Because each radiation fin 1 has a plurality of backwardly curved and crimped bottom mounting portions 11, the thickness of the bottom side of each radiation fin 1 is relatively increased, i.e., the contact surface area between the radiation fins 1 and the base member 3 is relatively increased for quick transmission of heat energy from the base member 3 to the radiation fins 1.

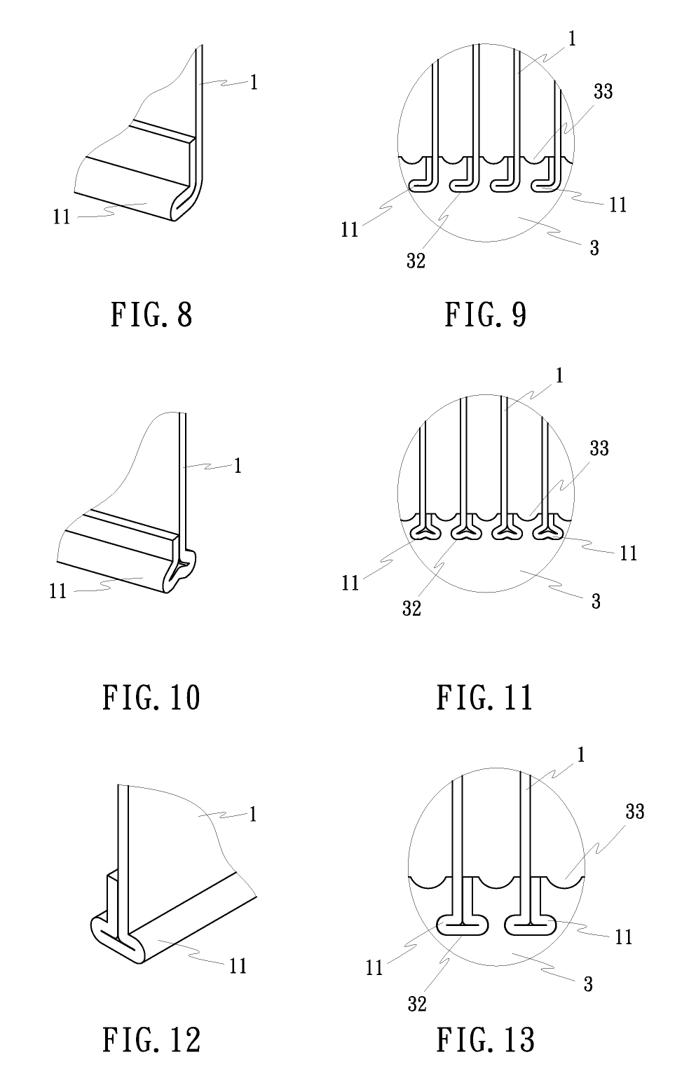

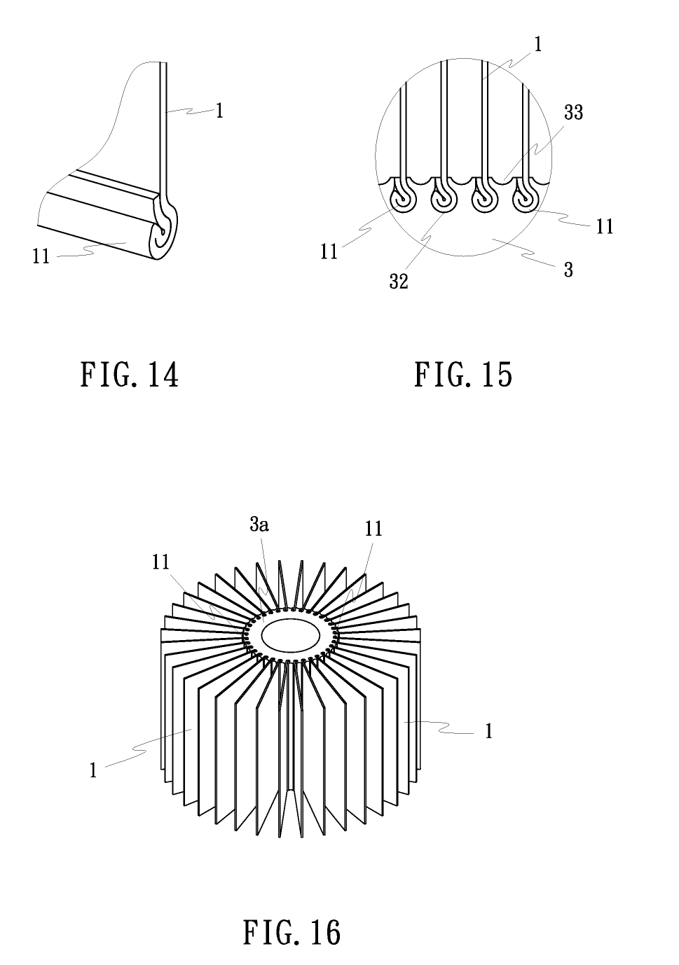

The backwardly curved bottom mounting portions 11 of the radiation fins 1 may be variously shaped. In FIG. 5, each backwardly curved bottom mounting portion 11 shows a U-shaped profile. In FIGS. 8 and 9, each backwardly curved bottom mounting portion 11 shows an L-shaped profile. In FIGS. 10 and 11, each backwardly curved bottom mounting portion 11 shows a substantially triangular profile. In FIGS. 12 and 13, each backwardly curved bottom mounting portion 11 shows an inverted T-shaped profile. In FIGS. 14 and 15, each backwardly curved bottom mounting portion 11 shows a scroll-shaped profile.

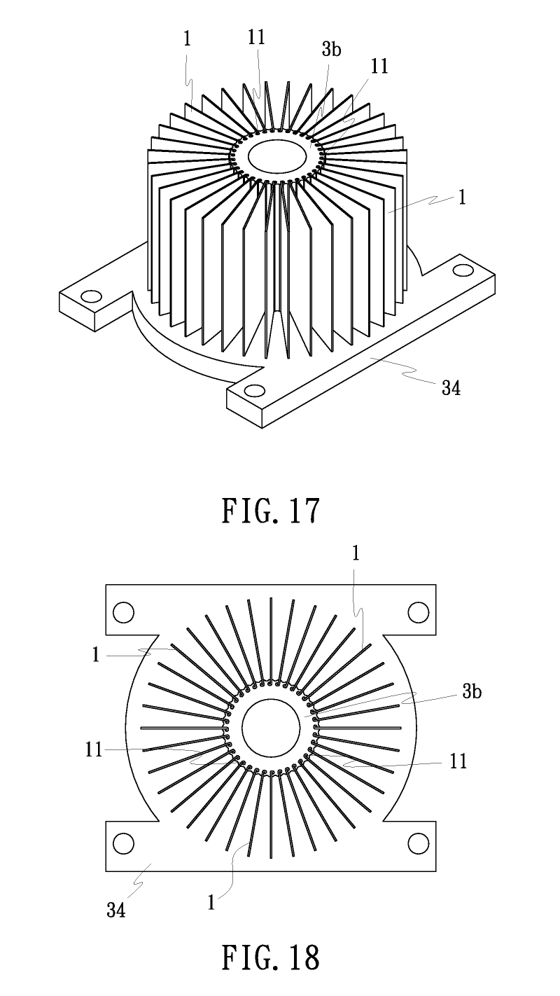

FIG. 16 shows a cooler device in accordance with a third embodiment of the present invention. According to this embodiment, the cooler device is comprised of a base member 3a and a plurality of radiation fins 1. The base member 3a is a metal cylinder having a plurality of deep transverse mounting grooves extending along the length and alternatively arranged in parallel around the periphery. The backwardly curved and crimped bottom mounting portions (not shown) of the radiation fins 1 are respectively fastened to the deep transverse mounting grooves of the base member 3a.

FIGS. 17 and 18 show a cooler device in accordance with a fourth embodiment of the present invention. According to this embodiment, the cooler device is comprised of a flat panel 34, a cylindrical base member 3a perpendicularly extended from the top side of the flat panel 34, and a plurality of radiation fins 1 radially fastened to the periphery of the cylindrical base member 3a. Alternatively, the cylindrical base member 3a and the flat panel 34 can be directly made from a metal material in one integral piece.

A prototype of cooler device has been constructed with the features of FIGS. 1˜18. The cooler device functions smoothly to provide all of the features disclosed earlier.

Although particular embodiments of the invention have been described in detail for purposes of illustration, various modifications and enhancements may be made without departing from the spirit and scope of the invention. Accordingly, the invention is not to be limited except as by the appended claims.

What is claimed is:

1. A cooler device comprising a metal base member, a plurality of metal radiation fins mounted on said metal base member, and at least one metal heat tube respectively filled with a working fluid and sealed and respectively fastened to said radiation fins, wherein said metal radiation fins each have at least one backwardly curved and crimped bottom mounting portion; said metal base member has a plurality of deep locating grooves formed on a surface thereof that receive the backwardly curved and crimped bottom mounting portions of said radiation fins; and said metal base member is compressed to fixedly secure the backwardly curved and crimped bottom mounting portions of said radiation fins to said metal base member.

2. The cooler device as claimed in claim 1, wherein said base member has a plurality of shadow grooves formed on the top wall thereof in parallel to said deep locating grooves and respectively spaced between each two adjacent deep locating grooves.

3. The cooler device as claimed in claim 1, wherein the backwardly curved and crimped bottom mounting portions of said metal radiation fins show a U-shaped profile.

4. The cooler device as claimed in claim 1, wherein the backwardly curved and crimped bottom mounting portions of said metal radiation fins show an L-shaped profile.

5. The cooler device as claimed in claim 1, wherein the backwardly curved and crimped bottom mounting portions of said metal radiation fins show a triangular profile.

6. The cooler device as claimed in claim 1, wherein the backwardly curved and crimped bottom mounting portions of said metal radiation fins show an inverted T-shaped profile.

7. The cooler device as claimed in claim 1, wherein the backwardly curved and crimped bottom mounting portions of said metal radiation fins show a scroll-shaped profile.

8. The cooler device as claimed in claim 1, wherein said metal base member is a flat solid rectangular metal panel.

9. The cooler device as claimed in claim 1, wherein said metal base member is a solid cylindrical metal member.

10. The cooler device as claimed in claim 1, further comprising a metal bottom panel formed integral with a bottom side of said base member.

11. A cooler device comprising a metal base member, and a plurality of metal radiation fins mounted on said metal base member, wherein said metal radiation fins each have a top side, at least one hooked portion respectively extending from the top side, a bottom side, and at least one backwardly curved and crimped bottom mounting portion respectively extending from the bottom side, the at least one hooked portion of one of said metal radiation fins being fastened to the at least one hooked portion of another one of said metal radiation fins; said metal base member has a plurality of deep locating grooves formed on a surface thereof that receive the backwardly curved and crimped bottom mounting portions of said radiation fins; and said metal base member is compressed to fixedly secure the backwardly curved and crimped bottom mounting portions of said radiation fins to said metal base member.

12. The cooler device as claimed in claim 11, wherein said base member has a plurality of shadow grooves formed on the top wall thereof in parallel to said deep locating grooves and respectively spaced between each two adjacent deep locating grooves.

13. The cooler device as claimed in claim 11, wherein the backwardly curved and crimped bottom mounting portions of said metal radiation fins show a U-shaped profile.

14. The cooler device as claimed in claim 11, wherein the backwardly curved and crimped bottom mounting portions of said metal radiation fins show an L-shaped profile.

15. The cooler device as claimed in claim 11, wherein the backwardly curved and crimped bottom mounting portions of said metal radiation fins show a triangular profile.

16. The cooler device as claimed in claim 11, wherein the backwardly curved and crimped bottom mounting portions of said metal radiation fins show an inverted T-shaped profile.

17. The cooler device as claimed in claim 11, wherein the backwardly curved and crimped bottom mounting portions of said metal radiation fins show a scroll-shaped profile.

18. The cooler device as claimed in claim 11, wherein said metal base member is a flat solid rectangular metal panel.

19. The cooler device as claimed in claim 11, wherein said metal base member is a solid cylindrical metal member.

20. The cooler device as claimed in claim 11, further comprising a metal bottom panel formed integral with a bottom side of said base member.
